(19) United States
(12) Patent Application Publication
(10) Pub. No.: US 2004/0252576 A1
(43) Pub. Date: Dec. 16, 2004

(54) Semiconductor memory element arrangement

(75) Inventors: Franz Hofmann, Munchen (DE); Richard Johannes Luyken, Munchen (DE); Michael Specht, Munchen (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 10/805,670

(22) Filed: Mar. 19, 2004

Related U.S. Application Data
(63) Continuation of application No. PCT/DE02/02742, filed on Jul. 25, 2002.

(30) Foreign Application Priority Data
Sep. 19, 2001 (DE) 101 46 215.8

(51) Int. Cl. G11C 8/02

(52) U.S. Cl. 365/232

(57) ABSTRACT

Method for fabricating a semiconductor memory element arrangement. A layer system, including a floating gate and a tunnel barrier arrangement formed on the floating gate, is formed on an electrically insulating layer. A first trench structure is formed in the layer system, and the first trench structure has first parallel trenches extending as far as the insulating layer. A second trench structure is formed in the layer system, and has second parallel trenches arranged perpendicular to the first trenches and extending as far as the insulating layer. First and second gate electrodes are formed in the first and second trench structures. The first gate electrode is adjacent to the floating gate through which first gate electrode electrical charge can be fed or can be dissipated from. The second gate electrode is adjacent to the tunnel barrier arrangement, and can control an electrical charge transmission of the tunnel barrier arrangement.

### CROSS-REFERENCE TO RELATED APPLICATION

This application is a continuation of International Patent Application Serial No. PCT/DE02/02742, filed Jul. 25, 2002, which published in German on Apr. 3, 2003 as WO 03/028107, and is incorporated herein by reference in its entirety.

### FIELD OF THE INVENTION

The invention relates to a method for fabricating a semiconductor memory element arrangement, a method for operating a semiconductor memory element arrangement and a semiconductor memory element arrangement.

### BACKGROUND OF THE INVENTION

Essential parameters of a semiconductor memory element arrangement are the retention time for which the memory content stored in the individual semiconductor memory elements is preserved, the write time required for programming in the memory content, and the write voltages required for programming in the memory content.

A known semiconductor memory element is the RAM memory element (RAM=Random Access Memory) which, although having relatively fast write times of a few nanoseconds, has only short retention times on account of unavoidable leakage currents, so that the RAM memory element has to be recharged at regular time intervals of about 100 ms.

By contrast, although the so-called EPROM memory element (EPROM=Electrically Programmable Read Only Memory) enables relatively long retention times of a number of years, the write times required for programming in the memory content are significantly longer than in the case of the RAM memory element.

There is therefore a need for semiconductor memory elements in which fast write times (of about 10 nanoseconds) are combined with long retention times (of more than one year) and low write voltages.

K. K. Likharev, “Layered tunnel barriers for non-volatile memory devices”, Applied Physics Letters Vol. 73, pages 2137-2139, has proposed a so-called “crested barrier” memory element, in which a floating gate is charged or discharged via a serial arrangement of (typically three) tunnel barriers, the tunnel barriers having a profiled (=“crested”) form. In this case, the tunnel barriers are not formed in the customary manner in the form of a square-wave potential with a constant height of the potential barrier, but rather are profiled by means of “peaks”.

Since, compared with a conventional tunnel barrier, such a “profiled” tunnel barrier has a greater charge transmission and a greater sensitivity for the voltage present, relatively fast write times can be achieved theoretically in any case with such a “crested barrier” semiconductor memory element. However, the write voltages required for writing are relatively large since the construction of the “crested barrier” structure requires layer structures with areally distributed nanocrystals arranged at a relatively large distance of approximately 3-5 nm from one another, in the case of which coupling between adjacent layers is relatively weak.

EP 0 908 954 A2, (“Semiconductor memory device and manufacturing method thereof”; Appl.: Hitachi Ltd.) has disclosed a proposal for a so-called PLED memory element (PLED=Planar Localized Electron Device), which has two word lines and also a source line, a drain line and a data line in a five-terminal arrangement. A multiple tunnel barrier is grown on a floating gate applied above a substrate. The PLED memory element has a write transistor and a read transistor. In this case, the substrate of the write transistor is formed by the multiple tunnel barrier and the gate of the write transistor is formed by the second word line. The floating gate itself forms the gate of the read transistor. In the case of this PLED memory element, it is possible to achieve short write times (similar to those of a RAM memory element) and long retention times (similar to those of a ROM memory element). Moreover, the required write voltages are significantly lower than in the case of the “crested barrier” memory element mentioned above.

However, the method for fabricating such a PLED memory element is relatively complicated, as is explained below.

In the known method for fabricating the PLED memory element, firstly a floating gate (memory node) is formed selectively on a substrate covered by a gate insulation layer, whereupon its side walls are covered by an insulating layer. A first gate electrode is formed by firstly applying a polysilicon layer over the whole area. Photoresist is then applied where the first gate electrode is intended to be formed, and an anisotropic etching step is carried out. Since the anisotropic etching is not effected in the horizontal direction, the polysilicon also remains on the side wall of the floating gate, thereby forming the first gate electrode.

Afterward, a multiple tunnel barrier is formed on the structure thus obtained, and a second gate electrode is formed adjacent to the multiple tunnel barrier and in a corresponding manner to the first gate electrode by whole-area application of a polysilicon layer, selective application of a photoresist and anisotropic etching of the polysilicon layer.

In order to simplify the fabrication process, EP 0 908 954 A2 also discloses combining the two word lines to form a common word line. During the operation of the PLED memory element, an electron transport across the multiple tunnel barrier is then made possible by application of an electrical voltage to the single word line, and the floating gate is correspondingly charged. The read process proceeds in such a way that a voltage is likewise applied to the word line in order to test how high the threshold voltage of the floating gate transistor is. However, the voltage applied to the word line during the read process reduces the blocking properties of the multiple tunnel barrier, so that the floating gate is partially discharged. Consequently, the charge on the floating gate is reduced somewhat during each read process, so that the read process is no longer effected in a manner free of disturbances.

U.S. Pat. No. 5,973,356 furthermore describes a large scale integrated flash memory, each memory cell containing four vertical floating gate transistors. Two mutually orthogonal gate lines enable the control gates to be addressed. First source/drain terminals can be addressed row by row by means of connecting lines arranged parallel to the first gate lines. Second source/drain terminals can be addressed row by row by means of connecting lines arranged parallel to the second gate lines.

DE 196 00 307 C1 describes a large scale integrated semiconductor memory having an EPROM cell formed in pillar-type fashion and having a floating gate and a control gate. The EPROM cell is fully depleted. The control gate of the EPROM cell is composed of p+-doped semiconductor material.

U.S. Pat. No. 6,211,531 B1 describes a vertical floating gate transistor having a multiplicity of tunnel barriers.

Furthermore, U.S. Pat. No. 5,952,692 A describes a memory device having a memory node, to which charge is written through a tunnel barrier arrangement. The stored charge influences the conductivity of the source/drain path. The tunnel barrier arrangement has a multiplicity of tunnel barriers, the tunnel barrier arrangement alternately having a 3 nm thick polysilicon layer and a 1 nm thick silicon nitride layer.

### SUMMARY OF THE INVENTION

Consequently, the invention is based on the problem of providing a method for fabricating a semiconductor memory element arrangement, a method for operating a semiconductor memory element arrangement and a semiconductor memory element arrangement which enable simpler fabrication whilst ensuring operation free of disturbances.

The problem is solved by means of the method for fabricating a semiconductor memory element arrangement, the method for operating a semiconductor memory element arrangement and the semiconductor memory element arrangement in accordance with the independent patent claims.

In a method for fabricating a semiconductor memory element arrangement, a first electrically insulating layer is applied on a substrate.

A layer system comprising a floating gate and a tunnel barrier arrangement applied on the floating gate is applied on the first electrically insulating layer.

A first gate electrode is formed adjacent to the floating gate, via which gate electrode electrical charge can be fed to the floating gate or can be dissipated from the latter.

A second gate electrode is formed adjacent to the tunnel barrier arrangement, via which gate electrode it is possible to control the electrical charge transmission of the tunnel barrier arrangement.

The first and second gate electrodes are formed in a first trench structure formed in the layer system, which trench structure comprises first trenches arranged parallel to one another and extending as far as the first insulating layer, and a second trench structure formed in the layer system, which trench structure comprises second trenches arranged parallel to one another and perpendicular to the first trenches and extending as far as the first insulating layer.

By virtue of the fact that firstly the floating gate and likewise the tunnel barrier arrangement are applied layer by layer on the substrate, then a first and second trench structure are formed in this layer sequence and only then are the first and second gate electrodes formed adjacent to the tunnel barrier arrangement and adjacent to the floating gate in said trench structures, the fabrication method according to the invention is simplified considerably in comparison with the known method. In this case, the two gate electrodes are formed as spacers in a self-aligning manner.

In the semiconductor element arrangement thus fabricated, data are written or erased by application of a positive electrical voltage to the second gate electrode and application of a negative or positive electrical voltage to the data line. The positive voltage present at the second gate electrode increases the electrical charge transmission of the tunnel barrier arrangement during the writing or erasing process and enables electrical charge to be fed to or dissipated from the floating gate and thus an inversion of the channel situated between source and drain regions in the substrate.

The read process is effected by application of a positive voltage to the first gate electrode in order to test the threshold voltage of the read transistor formed by the floating gate and the source or drain terminal. Thus, during reading, with an electrical voltage present between source and drain regions, depending on the inverted or noninverted state of the channel, a current flow is or is not detected in the channel.

The fact that only the first gate electrode is used for reading and only the second gate electrode is used for writing prevents a reduction of the electrical charge situated on the floating gate via the multiple tunnel barrier during the read process, so that reading can be effected in a manner free of disturbances.

In the semiconductor memory element arrangement fabricated by means of the method according to the invention, it is possible, moreover, to realize particularly high storage densities of 4*f² (f=“minimum feature size”), thereby achieving a highly dense arrangement of memory cells.

In accordance with a preferred embodiment, in order to form the first and second trench structures, a second electrically insulating layer is applied on the tunnel barrier arrangement and patterned in accordance with the first and second trench structures.

The patterning of the second electrically insulating layer applied on the tunnel barrier arrangement preferably has the following steps:

performance of a first photolithography step using a first photomask having a pattern of parallel strip-type openings whose width corresponds to the minimum feature size; and

performance of a second photolithography step using a second photomask having a pattern of parallel strip-type openings which are arranged perpendicular to the strip-type openings of the first photomask and whose width corresponds to the minimum feature size.

Preferably, after the first photolithography step and before the second photolithography step, spacers are formed on the second insulating layer in the first trenches.

The first trenches preferably have a smaller width than the second trenches.

The first and second gate electrodes are preferably formed as spacers in the second trenches of the second trench structure.

In accordance with a preferred embodiment, the step of forming the first gate electrode in the first and second trench structures has the following steps:

application of a third electrically insulating layer on the sidewalls of the first and second trench structures;

application of a first polysilicon layer on the third electrically insulating layer with filling of the width of the first trenches and formation of first polysilicon spacers in the second trenches in order to form the first gate electrode.

In accordance with a preferred embodiment, the step of forming the second gate electrode in the first and second trench structures has the following steps:

application of a fourth electrically insulating layer on the first polysilicon layer;

application of a second polysilicon layer on the third and fourth electrically insulating layers with filling of the width of the first trenches and formation of second polysilicon spacers in the second trenches in order to form the second gate electrode.

The first, second, third and fourth insulating layers may be formed for example from silicon nitride or silicon dioxide.

The first and second gate electrodes are preferably formed from polysilicon.

The tunnel barrier arrangement is preferably formed as a layer stack with an alternating layer sequence of semiconducting and insulating layers for the purpose of forming a multiple tunnel barrier.

The semiconductor layers of the layer stack are preferably formed from undoped polysilicon, whereas the insulating layers of the layer stack are preferably formed from silicon nitride or silicon dioxide.

In accordance with a preferred embodiment, the semiconducting layers of the layer stack are formed with a thickness in the range of 30 to 50 nm and the insulating layers being formed with a thickness in the range of 2 to 4 nm.

In accordance with a preferred embodiment, the semiconducting layers of the layer stack are formed with a thickness and also a grain size of at most 2 nm and the insulating layers being formed with a thickness of at most 1.5 nm. In this case, the conductive layers form very thin layers of fine-grained crystals (e.g., polysilicon crystals). Such a thin layer of polycrystalline silicon may be regarded as a two-dimensional lattice of conductive islands connected to one another by very small capacitances.

In this case, the distances between the nanocrystals made of polysilicon are readily controllable. A Coulomb blockage can thus be used in a targeted manner, so that the write time of the memory cell is shortened further. The vertical isolation of a plurality of such layers by insulating layers, e.g., made of silicon dioxide, leads in the vertical direction to a regular lattice of conductive islands connected to one another by readily adjustable electrical resistances.

As an alternative, the semiconducting layers may also be formed from amorphous silicon.

In a method for operating a semiconductor memory element arrangement having a first electrically insulating layer applied on a substrate and a layer system comprising a floating gate and a tunnel barrier arrangement applied on the floating gate, said layer system being applied on the first electrically insulating layer; the electrical charge transmission of the tunnel barrier arrangement to the floating gate is controlled via a second gate electrode, the first and second gate electrodes being formed in a first trench structure formed in the layer system, which trench structure comprises first trenches arranged parallel to one another and extending as far as the first insulating layer, and a second trench structure formed in the layer system, which trench structure comprises second trenches arranged parallel to one another and perpendicular to the first trenches and extending as far as the first insulating layer.

Preferably, for reading data of the semiconductor memory element arrangement, an electrical voltage is applied to the first gate electrode with the second gate electrode free of voltage.

Preferably, for writing or erasing data of the semiconductor memory element arrangement, an electrical voltage is applied to the second gate electrode with the first gate electrode free of voltage.

In a semiconductor memory element arrangement, in which a plurality of semiconductor memory elements are arranged in a matrix-like manner in a plurality of rows and columns, each semiconductor memory element has

a first electrically insulating layer applied on a substrate,

a layer system comprising a floating gate and a tunnel barrier arrangement applied on the floating gate, said layer system being applied on the first electrically insulating layer;

a first gate electrode adjacent to the floating gate and serving for reading the state of the floating gate transistor; and

a second gate electrode adjacent to the tunnel barrier arrangement, via which gate electrode it is possible to control the charge transmission of the tunnel barrier arrangement;

the first and second gate electrodes being formed in a first trench structure formed in the layer system, which trench structure comprises first trenches arranged parallel to one another and extending as far as the first insulating layer, and a second trench structure formed in the layer system, which trench structure comprises second trenches arranged parallel to one another and perpendicular to the first trenches and extending as far as the first insulating layer.

### BRIEF DESCRIPTION OF THE DRAWINGS

Exemplary embodiments of the invention are illustrated in the figures and explained in more detail below.

FIGS. 1a-1g show cross sections of a semiconductor memory element arrangement in accordance with an exemplary embodiment of the invention at different states during its fabrication;

FIGS. 2a-2g show cross sections of the semiconductor memory element arrangement from FIG. 1 at corresponding states during its fabrication in a perpendicular sectional direction with respect to FIG. 1;

FIGS. 3a-3c show diagrammatic illustrations of the photomasks used during the fabrication of the semiconductor memory element arrangement in accordance with FIGS. 1 and 2;

FIG. 4 shows a diagrammatic illustration of a semiconductor memory element arrangement according to the invention in plan view; and

FIG. 5 shows a programming example of the semiconductor memory element arrangement from FIG. 4.

### DETAILED DESCRIPTION OF THE PREFERRED MODE OF THE INVENTION

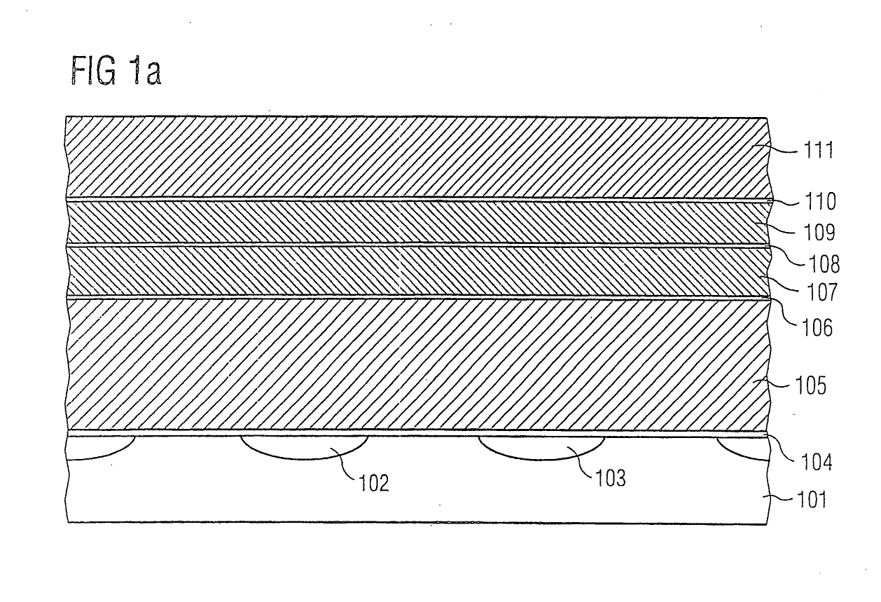

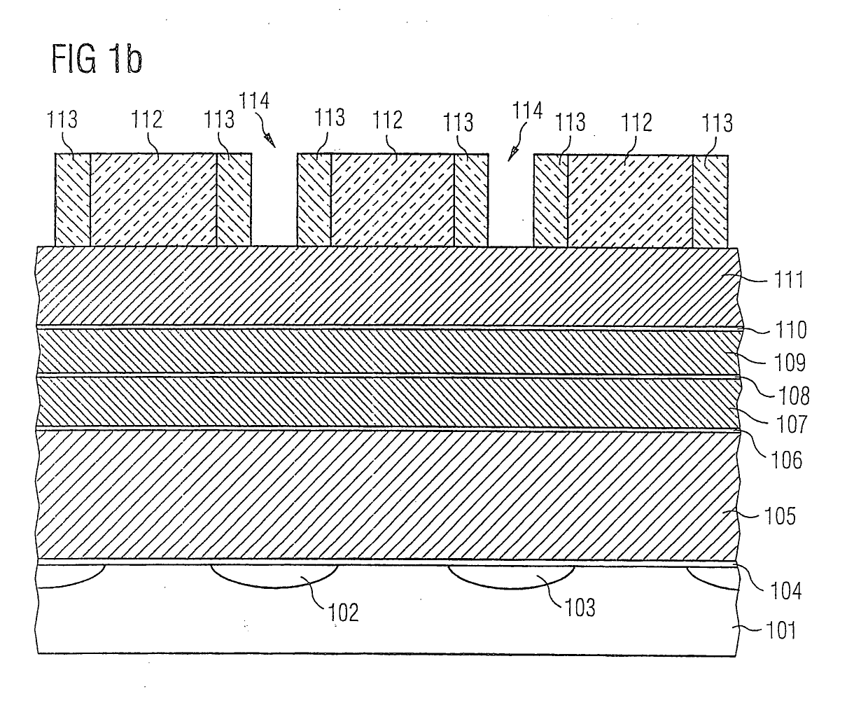

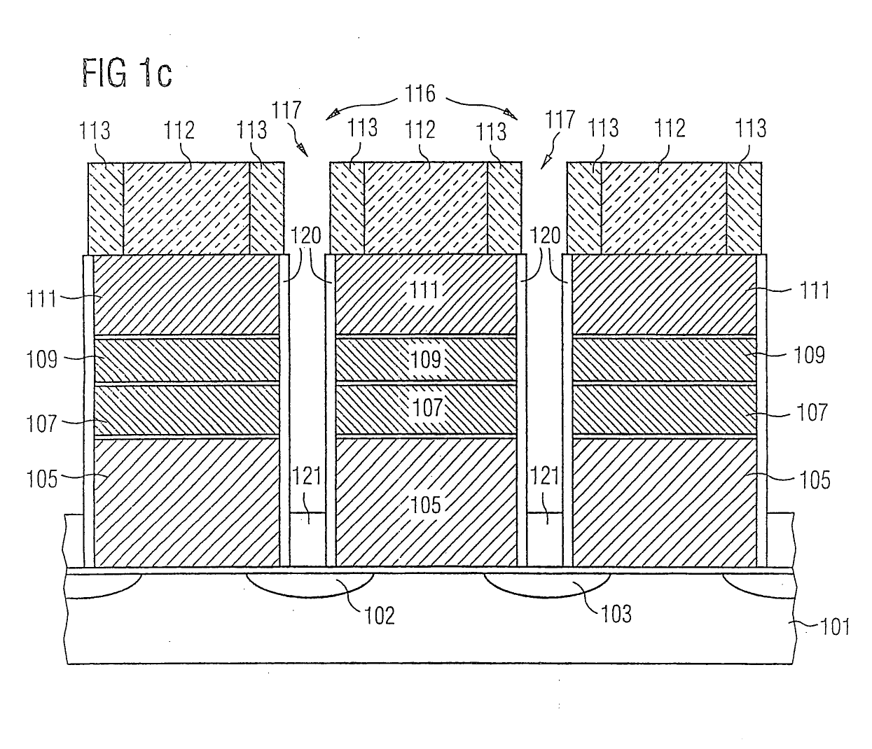

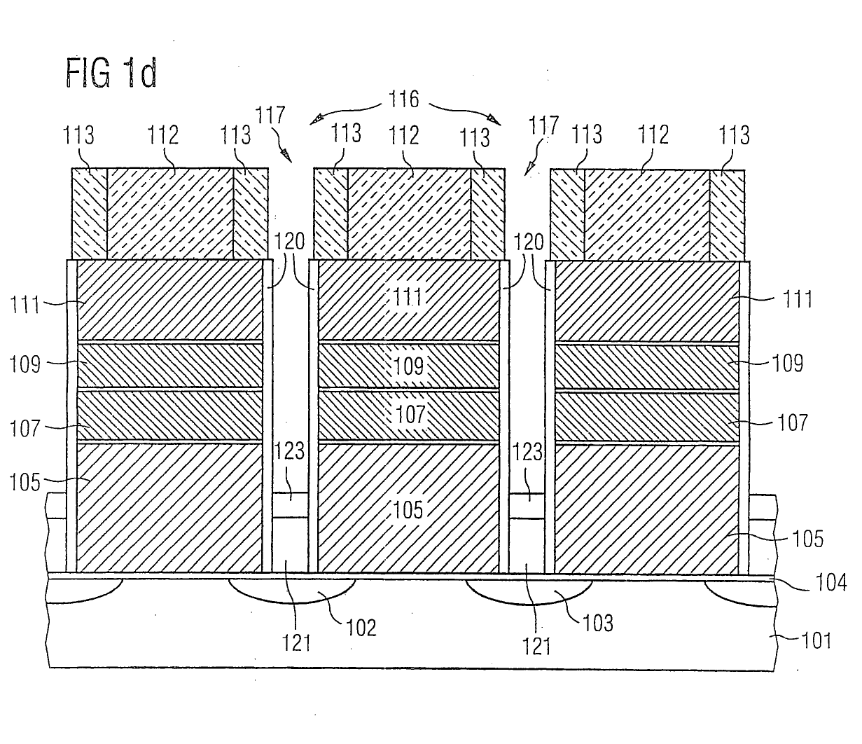

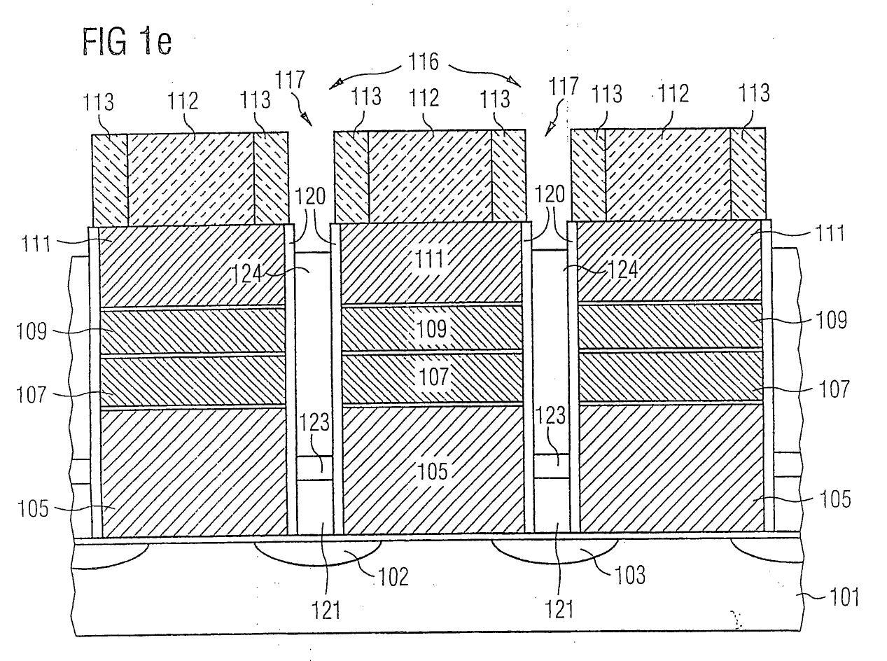

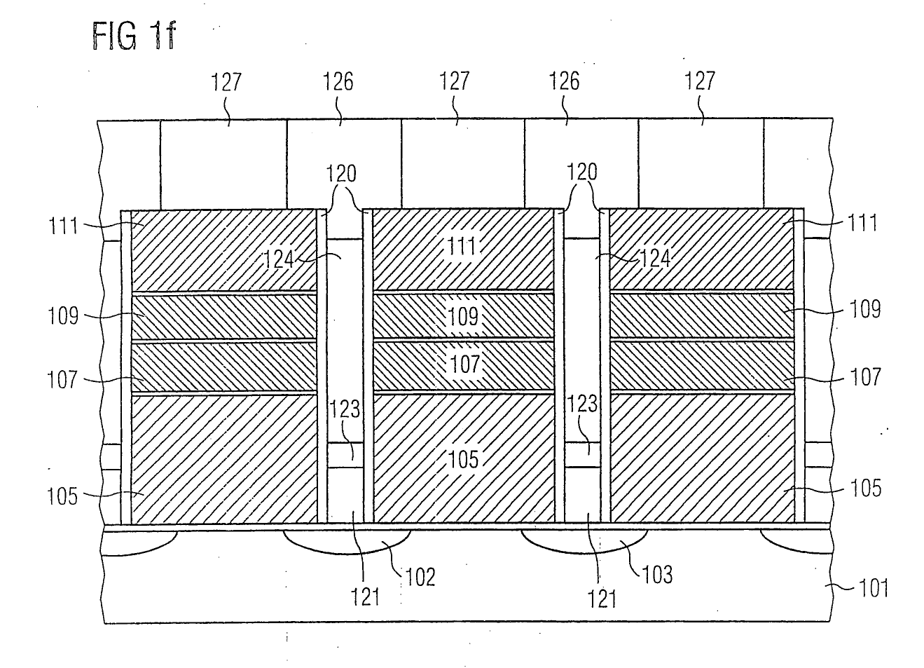

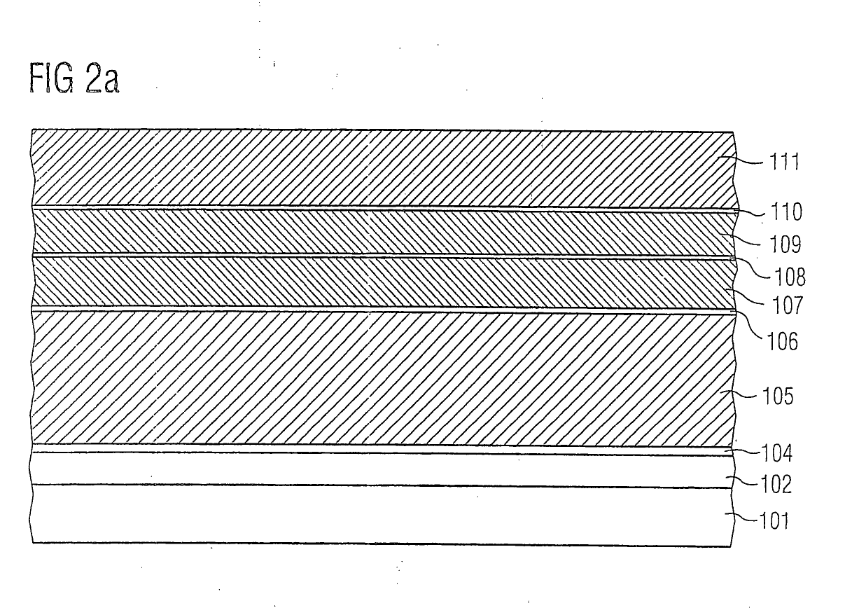

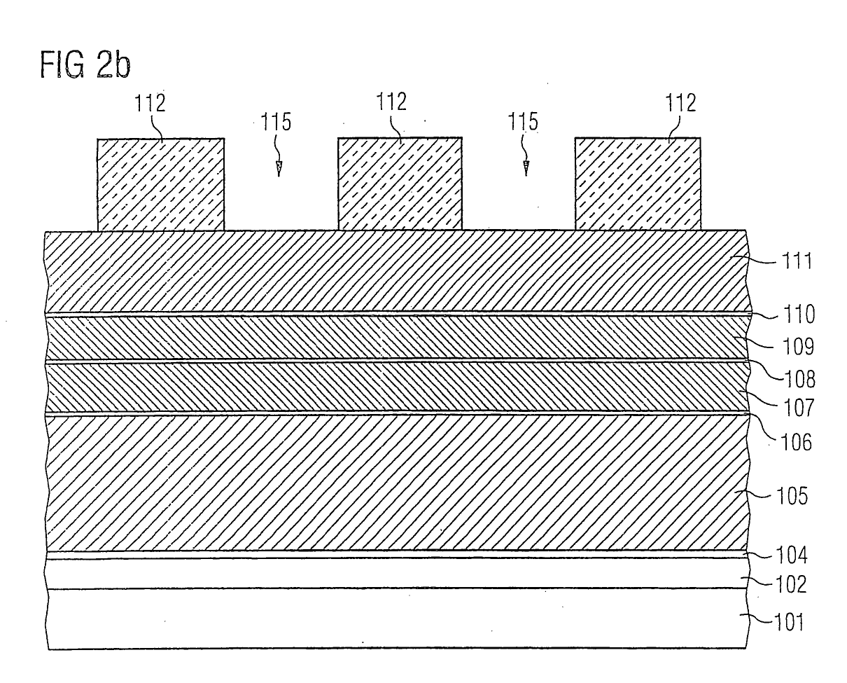

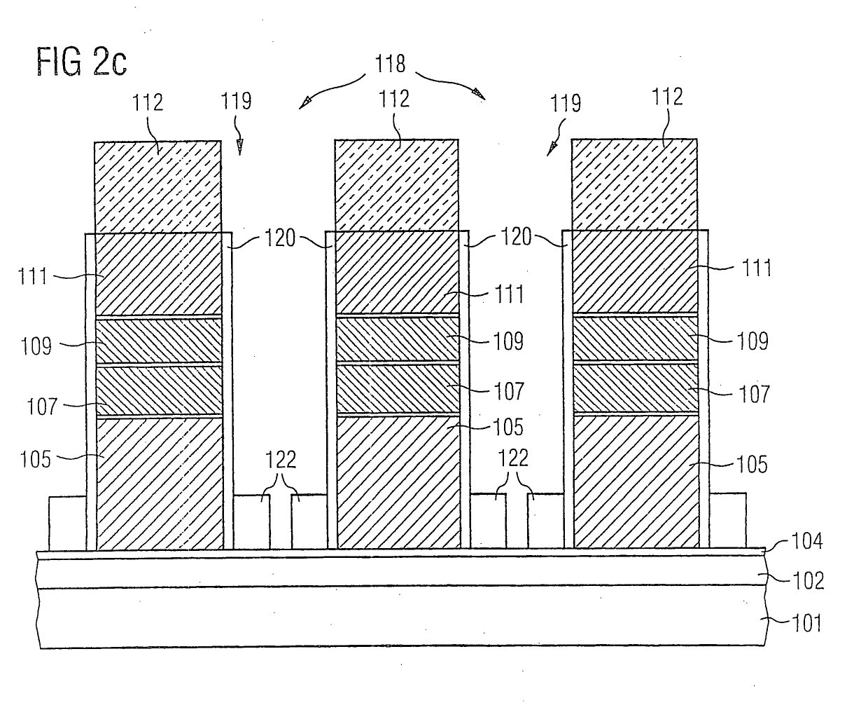

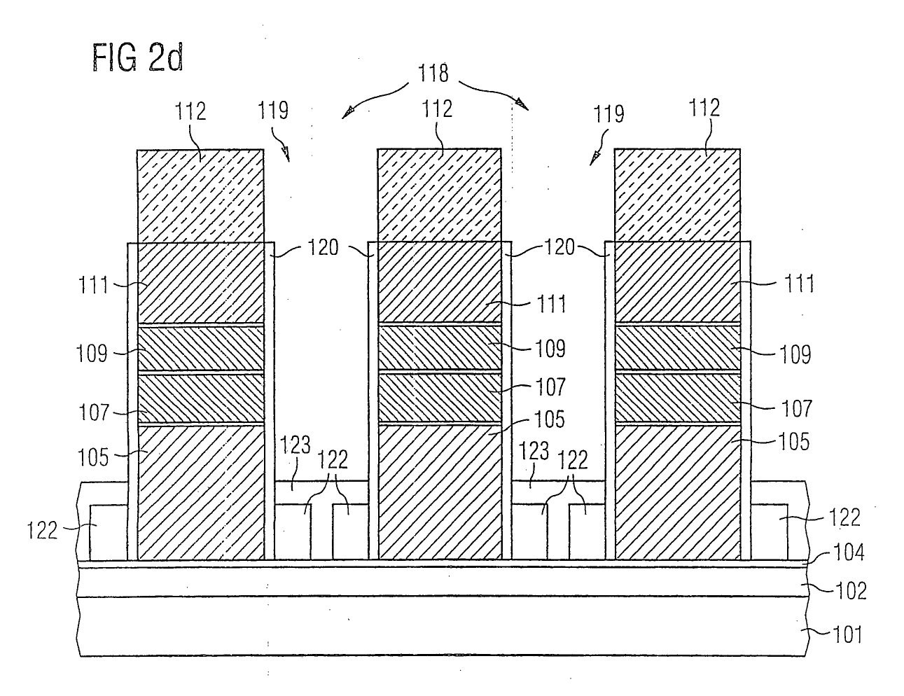

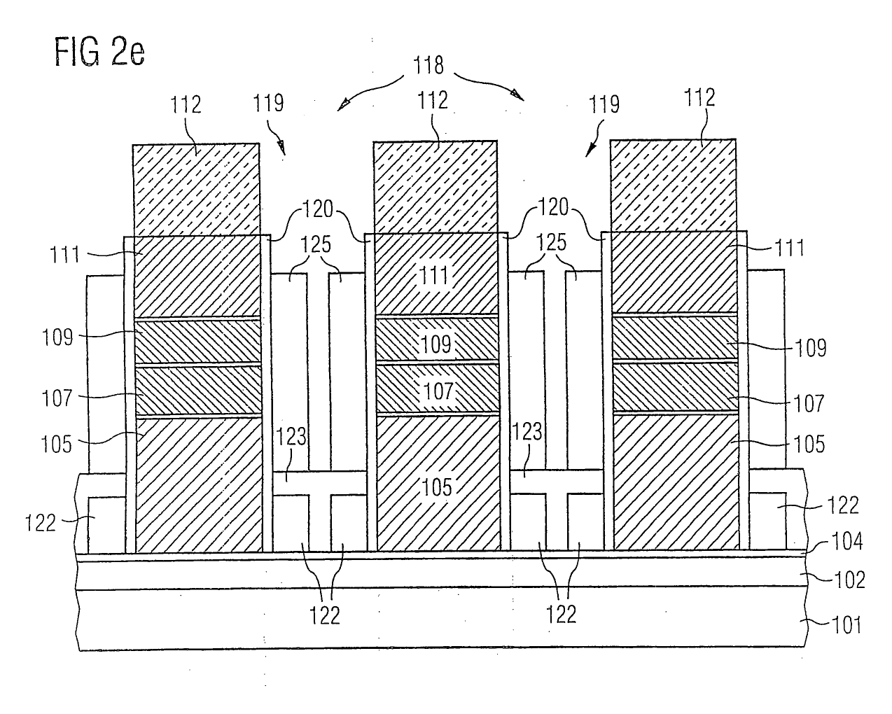

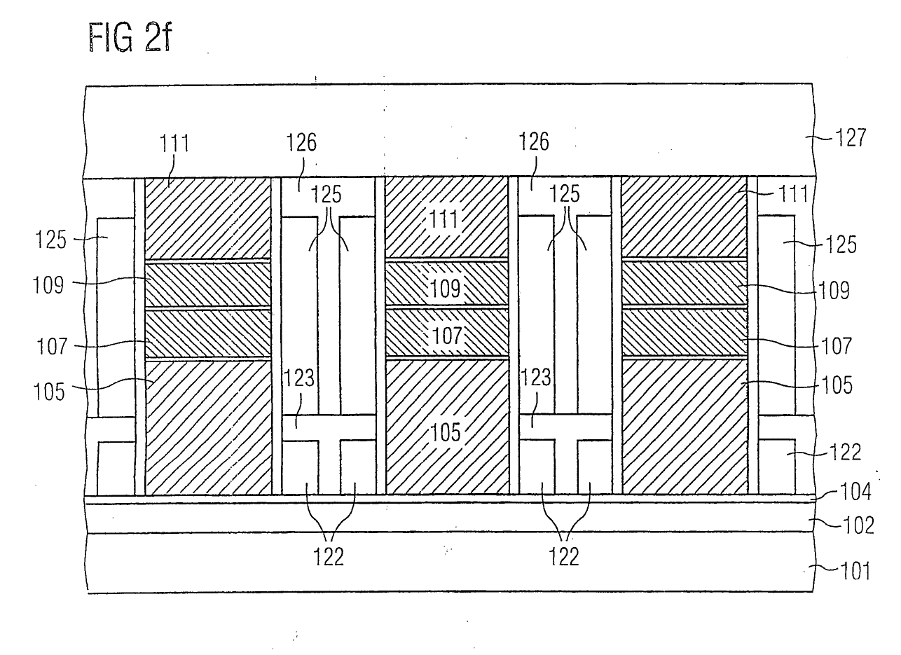

A method for fabricating a semiconductor memory element arrangement in accordance with a preferred exemplary embodiment is explained with reference to FIGS. 1a-g and FIGS. 2a-g, the cross-sectional views illustrated in FIGS. 1a-g and FIGS. 2a-g respectively being illustrated for mutually perpendicular sectional planes.

In accordance with FIG. 1a, firstly a layer system comprising a floating gate and a tunnel barrier arrangement applied on the floating gate is formed on a substrate.

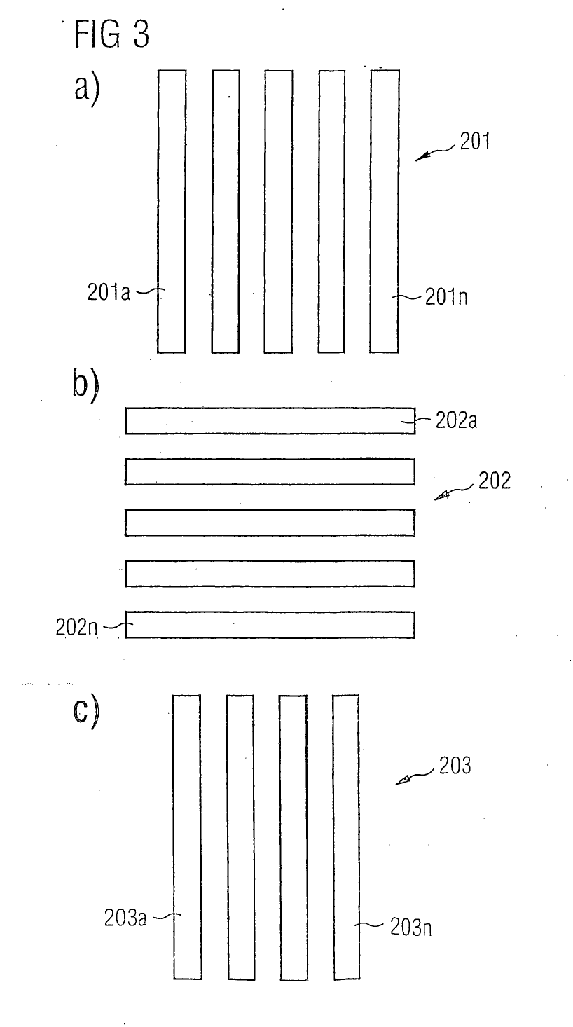

For this purpose, in a first step, a silicon substrate 101 is covered by means of an implantation mask, whereupon an arsenic implantation with a dose of about 10¹⁶ cm⁻³ is carried out in order to form source and drain regions 102, 103 in the silicon substrate 101. The implantation mask 203 used in this case is illustrated diagrammatically in FIG. 3c and has a pattern of strip-type openings 203a, . . . , 203n which are arranged parallel to one another and the distance between which corresponds to the desired distance between the source and drain regions 102, 103.

Afterward, an electrically insulating layer 104 made of silicon dioxide having a thickness of about 6-10 nm is grown on the silicon substrate. The vapor phase deposition method (CVD=chemical vapor deposition) is employed for growing the layer 104, and likewise for growing the subsequent layers.

A layer 105 made of polysilicon having a thickness of approximately 50 nm is grown on the layer 104. The layer 105 serves for forming a floating gate of the semiconductor memory element arrangement 100.

Electrically insulating barrier layers 106, 108 and 110 made of silicon nitride (Si₃N₄) and semiconducting layers 107, 109 and 111 made of polysilicon are grown in an alternating layer sequence on the layer 105. The layer stack formed from the electrically insulating and semiconducting layers 106-110 serves for forming a multiple tunnel barrier of the semiconductor memory element arrangement 100.

In the exemplary embodiment illustrated, the polysilicon layers 107 and 109 have a thickness of approximately 40 nm, the polysilicon layer 111 has a thickness of approximately 50 nm, and the barrier layers 106, 108 and 110 have a thickness of approximately 2 nm.

In a next step, in accordance with FIG. 1b and FIG. 2b, a second electrically insulating layer 112 made of silicon nitride is applied on the polysilicon layer 111.

In a first photolithography step using a first photomask 201, which is illustrated diagrammatically in FIG. 3a, trenches arranged parallel to one another and having a width of approximately 150 nm are etched into the second electrically insulating layer 112. The photomask 201 has a multiplicity of strip-type openings 201a, . . . , 201n which are arranged parallel to one another and the distance between which corresponds to the minimum feature size (e.g., 150 nm).

The silicon nitride is subjected to dry etching using the photomask 201.

After the removal of the photoresist, silicon nitride is again applied to the uncovered regions of the polysilicon layer 111, whereupon a spacer etching for the purpose of forming silicon nitride spacers 113 is carried out in accordance with FIG. 1b. First trenches 114 having a width of approximately 50 nm are formed as a result.

Afterward, as can be seen from FIG. 2b, a second photolithography step is carried out using a second photomask 202, which is illustrated diagrammatically in FIG. 3b.

The photomask 202 has, like the photomask 201, a multiplicity of strip-type openings 202a, . . . , 202n which are arranged parallel to one another and the distance between which corresponds to the minimum feature size (e.g., 150 nm). The second photomask is positioned perpendicular to the first photomask. The silicon nitride is then subjected to dry etching, so that, in accordance with FIG. 2b, second trenches 115 having a width of approximately 150 nm are formed perpendicular to the first trenches 114 illustrated in FIG. 1b. The photoresist is subsequently removed.

In a next step, in accordance with FIG. 1c and FIG. 2c, those regions of the layer structure comprising polysilicon layer 111, multiple tunnel barrier 106-110 and floating gate 105 which are not covered by silicon nitride are etched, thereby forming a first trench structure 116 with mutually parallel trenches 117, cf., FIG. 1c, and a second trench structure 118 with second trenches 119 arranged parallel to one another and perpendicular to the first trenches 117, cf., FIG. 2c. The first and second trenches 117, 119 in each case extent parallel to the stack direction of the layer stack 106-110 as far as the electrically insulating silicon dioxide layer 104.

Afterward, a third electrically insulating layer 120 made of silicon dioxide is applied on the side walls of the first and, respectively, second trench structure 116, 118. A polysilicon layer 121 is applied on the third electrically insulating layer 120. The polysilicon layer 121 has a layer thickness of approximately 50 nm, so that polysilicon spacers 122 are formed in the second trench structure 118.

The polysilicon layer 121 and, respectively, the polysilicon spacers 122 serve for forming the first gate electrode, which serves for reading the state of the floating gate transistor, i.e., for determining the electrical charge carriers stored in the floating gate.

After a process of etching back the polysilicon layer 121 and, respectively, the polysilicon spacers 122, in a next step in accordance with FIG. 1d and FIG. 2d, a fourth electrically insulating layer 123 made of silicon dioxide is applied and subsequently etched back, in accordance with FIG. 2d the regions between the polysilicon spacers 122 being completely filled with silicon dioxide and the polysilicon layer 121 and the polysilicon spacer 122 still remaining covered by the fourth electrically insulating layer 123 made of silicon dioxide.

In accordance with FIG. 1e and FIG. 2e, a polysilicon layer 124 is again applied to the insulating layer 123 made of silicon dioxide. Like the polysilicon layer 121, the polysilicon layer 124 has a layer thickness of approximately 50 nm, so that polysilicon spacers 125 are formed in the second trench structure 118. The height of the polysilicon layer 124 and the polysilicon spacers 125 form an at least partial lateral overlap with the polysilicon layer 111.

The polysilicon layer 124 and, respectively, the polysilicon spacers 125 serve for forming the second gate electrode, it being possible to control the electrical charge transmission of the multiple tunnel barrier by application of an electrical voltage to the second gate electrode.

In accordance with the illustration in FIG. 1e and FIG. 2e, the height of the floating gate 105 projects somewhat above the region of the insulating layer 123, so that the floating gate 105, on the one hand, and the polysilicon layer 124 and, respectively, the polysilicon spacers 125, on the other hand, overlap one another in the vertical direction in order to form the second gate electrode. However, in the context of the fabrication or in the context of the choice of the individual layer thicknesses, care must be taken to ensure that this overlapping region is as small as possible in order to prevent a disturbing interaction between the second gate electrode and the floating gate 105 during the writing or erasing of data in the semiconductor element arrangement 100.

In a next step, the layers 112, 113 made of silicon nitride are completely etched away, whereupon, in accordance with FIG. 1f and FIG. 2f, a fifth electrically insulating layer 126 made of silicon dioxide is firstly deposited and subsequently smoothed by means of CMP (=chemical mechanical polishing). A trench is etched into the layer 126 by means of photolithography. After the deposition of a tungsten layer 127, the data line 127 is patterned using chemical mechanical polishing (CMP). The semiconductor memory element arrangement 100 is thus completed.

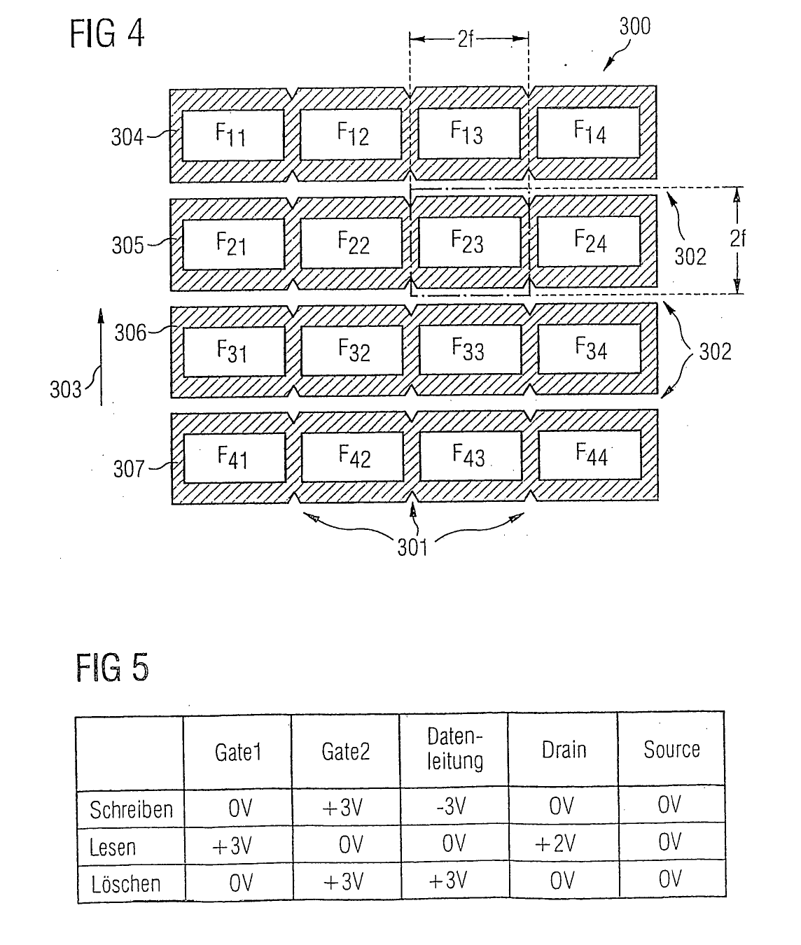

FIG. 4 diagrammatically illustrates a semiconductor memory element arrangement 300 fabricated according to the method described above in plan view.

The semiconductor memory element arrangement 300 has a total of sixteen semiconductor memory elements F₁₁, F₁₂, . . . , F₄₄ arranged in a matrix-like manner. Each semiconductor memory element F₁₁, F₁₂, . . . , F₄₄ has, as described above, a floating gate on which a multiple tunnel barrier is respectively applied.

Extending between the semiconductor memory elements F₁₁, F₁₂, . . . , F₄₄ is a first trench structure 301 in the vertical direction and a second trench structure 302 in the horizontal direction. The first and second gate electrodes are formed in the regions 304 illustrated in hatched fashion in FIG. 4.

In accordance with FIG. 4, the first and second gate electrodes extend perpendicularly to the plane of the drawing in the first and second trench structures 301, 302, the first gate electrodes being formed adjacent to the floating gates and the second gate electrodes being formed adjacent to the multiple tunnel barriers of the semiconductor memory elements F₁₁, F₁₂, . . . , F₄₄.

As described above, the content of each memory cell can thus be read by application of an electrical voltage to the first gate electrode. The electrical charge transmission of the multiple tunnel barrier of each memory cell can be controlled by application of an electrical voltage to the second gate electrode.

The direction of the source and drain regions and of the data line is represented by the arrow 303.

As can be seen from FIG. 4 and also from the fabrication process illustrated in FIG. 1 and FIG. 2, the first and second trench structures 301, 302 have a different width. Whereas in the first trench structure 301 the entire width of the trenches formed is filled by polysilicon in order to form the first and second gate electrodes, in the second trench structure 302 the first and second gate electrodes are formed as spacers. Consequently, in each case two first and second gate electrodes are formed in the second trench structure, said gate electrodes being isolated from one another by an electrically insulating layer running between the respective spacers.

As is shown in FIG. 4 using the example of the semiconductor memory element F₂₃, in this case each of the semiconductor memory elements F₁₁, . . . , F₄₄ has an area of (2f)* (2f)=4*f², where “f” represents the so-called minimal feature size. The semiconductor memory element arrangement 300 thus forms a highly dense grid structure. The arrangement of the individual memory cells in this case corresponds to a so-called “virtual ground array”.

A programming example of the semiconductor memory element arrangement 300 from FIG. 4 is explained with reference to FIG. 5.

Accordingly, in accordance with the exemplary embodiment illustrated, data are written in the semiconductor memory element arrangement 300 by application of a positive voltage of +3 Volts to the second gate electrode and application of a negative voltage of −3 Volts to the data line 210. Data are erased correspondingly by application of a positive voltage of +3 Volts to the second gate electrode and application of a positive voltage of +3 Volts to the data line.

The voltage of +3 Volts present at the second gate electrode increases the electrical charge transmission of the multiple tunnel barrier during the writing or erasing process and enables electrical charge to be fed to or dissipated from the floating gate 105 and thus an inversion of the channel situated between the source and drain regions.

In accordance with the exemplary embodiment illustrated, data are read in the semiconductor memory element arrangement 300 by application of a positive voltage of +3 Volts to the first gate electrode and application of a lower positive voltage of +2 Volts, for example, to all the drain lines, while all the source lines are set to 0 Volts.

The writing of data in the semiconductor memory element arrangement 300 corresponds to the setting of a logic “1” and the erasure corresponds to the setting of a logic “0”. The setting of these logic values always takes place on the entire addressed word line with the aid of the corresponding data lines. During reading, a voltage of +3 Volts is applied to the first gate electrode and, upon application of a low voltage of +2 Volts to the drain line, consequently depending on the inverted or noninverted state of the channel, a current flow in the channel is detected (corresponding to a bit “1”) or is not detected (corresponding to a bit “0”).

The fact that only the first gate electrode is used for reading data from the semiconductor memory element arrangement according to the invention and only the second gate electrode is used for writing data prevents a reduction of the electrical charge situated on the floating gate via the multiple tunnel barrier during the read process, so that the read process can be effected in a manner free of disturbances.

1-19. (Canceled).

20. A method for fabricating a semiconductor memory element arrangement, comprising the steps of:
forming a first electrically insulating layer on a substrate;
forming a layer system, including a floating gate and a multiple tunnel barrier arrangement formed on the floating gate, on the first electrically insulating layer;
forming a first trench structure in the layer system, the first trench structure having first trenches arranged parallel to one another and extending as far as the first electrically insulating layer;
forming a second trench structure in the layer system, the second trench structure having second trenches arranged parallel to one another and extending as far as the first electrically insulating layer, the second trenches being arranged perpendicular to the first trenches;
forming, in the first and second trench structures, a first gate electrode adjacent to the floating gate through which first gate electrode electrical charge can be fed or can be dissipated from; and
forming, in the first and second trench structures, a second gate electrode adjacent to the tunnel barrier arrangement, wherein through the second gate electrode an electrical charge transmission of the multiple tunnel barrier arrangement can be controlled.

21. The method as claimed in claim 20, wherein the steps of forming the first and second trench structures comprise the steps of:
forming a second electrically insulating layer on the multiple tunnel barrier arrangement; and
patterning the second electrically insulating layer in accordance with the first and second trench structures.

22. The method as claimed in claim 21, wherein the step of patterning the second electrically insulating layer comprises the steps of:
performing a first photolithography step by using a first photomask having a pattern of parallel strip-type openings whose width corresponds to the minimum feature size of the first trenches; and
performing a second photolithography step using a second photomask having a pattern of parallel strip-type openings which are arranged perpendicular to the strip-type openings of the first photomask and whose width corresponds to the minimum feature size of the second trenches.

23. The method as claimed in claim 22, further comprising the step of, after the first photolithography step and before the second photolithography step, forming spacers on the second electrically insulating layer in the first trenches.

24. The method as claimed in claim 20, wherein the first trenches have a smaller width than the second trenches.

25. The method as claimed in claim 20, wherein the first and second gate electrodes are formed as spacers in the second trenches of the second trench structure.

26. The method as claimed in claim 21, wherein the step of forming the first gate electrode in the first and second trench structures comprises the steps of:
applying a third electrically insulating layer on the sidewalls of the first and second trench structures; and
applying a first polysilicon layer on the third electrically insulating layer with filling of the width of the first trenches and formation of first polysilicon spacers in the second trenches in order to form the first gate electrode.

27. The method as claimed in claim 26, wherein the step of forming the second gate electrode in the first and second trench structures comprises the steps of:
applying a fourth electrically insulating layer on the first polysilicon layer; and
applying a second polysilicon layer on the third and fourth electrically insulating layers with filling of the width of the first trenches and formation of second polysilicon spacers in the second trenches in order to form the second gate electrode.

28. The method as claimed in claim 27, wherein the first, second, third and fourth electrically insulating layers are formed from silicon nitride or silicon dioxide.

29. The method as claimed in claim 20, wherein the first and second gate electrodes are formed from polysilicon.

30. The method as claimed in claim 20, wherein the multiple tunnel barrier arrangement comprises a layer stack of an alternating layer sequence of semiconducting and insulating layers.

31. The method as claimed in claim 30, wherein the semiconducting layers of the layer stack are formed from undoped polysilicon.

32. The method as claimed in claim 30, wherein the insulating layers of the layer stack are formed from silicon nitride or silicon dioxide.

33. The method as claimed in claim 30, wherein the semiconducting layers of the layer stack are formed with a thickness in a range of 30 to 50 nm and the insulating layers are formed with a thickness in a range of 2 to 4 nm.

34. The method as claimed in claim 30, wherein the semiconducting layers of the layer stack are formed with a thickness and also a grain size of at most 2 nm and the insulating layers are formed with a thickness of at most 1.5 nm.

35. A method for operating a semiconductor memory element arrangement having a first electrically insulating layer formed on a substrate and a layer system comprising a floating gate and a tunnel barrier arrangement formed on the floating gate, the layer system being formed on the first electrically insulating layer and forming a multiple tunnel barrier, wherein first and second gate electrodes are formed in a first trench structure formed in the layer system, the first trench structure including first trenches arranged parallel to one another and extending as far as the first electrically insulating layer, and a second trench structure formed in the layer system, the second trench structure including second trenches arranged parallel to one another and perpendicular to the first trenches and extending as far as the first insulating layer, the method comprising the steps of:
reading the electrical potential on the floating gate via the first gate electrode; and
controlling the electrical charge transmission of the tunnel barrier arrangement via the second gate electrode.

36. The method as claimed in claim 35, further comprising the step of reading data of the semiconductor memory element arrangement by applying an electrical voltage to the first gate electrode with the second gate electrode free of voltage.

37. The method as claimed in claim 35, further comprising the step of writing or erasing data of the semiconductor memory element arrangement by applying an electrical voltage to the second gate electrode with the first gate electrode free of voltage.

38. A semiconductor memory element arrangement, in which a plurality of semiconductor memory elements are arranged in a matrix-like manner in a plurality of rows and columns, each semiconductor memory element comprising:
an electrically insulating layer formed on a substrate;
a layer system formed on the electrically insulating layer, wherein the layer system includes a floating gate and a tunnel barrier arrangement formed on the floating gate and forming a multiple tunnel barrier;
a first trench structure formed in the layer system and having first trenches arranged parallel to one another and extending as far as the electrically insulating layer;
a second trench structure formed in the layer system and having second trenches arranged parallel to one another and perpendicular to the first trenches and extending as far as the electrically insulating layer;
a first gate electrode formed in the first and second trench structures and adjacent to the floating gate, wherein the first gate electrode determines the charge carriers stored in the floating gate; and
a second gate electrode formed in the first and second trench structures and adjacent to the tunnel barrier arrangement, wherein via the second gate electrode the charge transmission of the tunnel barrier arrangement may be controlled.
